(19) United States
(12) Patent Application Publication
(10) Pub. No.: US 2009/0315568 A1
(43) Pub. Date: Dec. 24, 2009

(54) Manually Pre-Settable Proof of Flow Current Sensor Apparatus, System, and/or Method

(76) Inventors: Kent Jeffrey Holce, Portland, OR (US); Rodrick Eren Seely, Sherwood, OR (US); William Forrest Hudson, Cornelius, OR (US)

Correspondence Address: NORTHWEST IP LAW GROUP, P. O. BOX 3703, PORTLAND, OR, 97208-3703, US

(21) Appl. No.: 12/351,803

(22) Filed: Jan. 9, 2009

Related U.S. Application Data
(60) Provisional application No. 61/010,471, filed on Jan. 9, 2008.

(51) Int. Cl. G01R 31/34; G01R 17/02

(52) U.S. Cl. 324/555; 324/99 R

(57) ABSTRACT

The present invention relates to motor status monitoring and equipment protection applications for industrial automation, HVAC, and other implementations, and more particularly, to use of current sensors in detecting loss of flow conditions. Presently described embodiments can comprise simplified, compact current sensors devices that can be economical to build, inventory, distribute, and purchase, and can be easily manually configured prior to installation and automatically offer proof of flow detection once properly installed and energized.

### RELATED APPLICATIONS

This application is a nonprovisional of, and claims priority from, U.S. Provisional Patent Application No. 61/010,471, filed Jan. 9, 2008, entitled “Manually Settable Proof of Flow Current Sensor Apparatus, System, and/or Method,” which is hereby incorporated by reference in its entirety.

### COPYRIGHT NOTICE

© Senva, Inc. A portion of the disclosure of this patent document contains material that is subject to copyright protection. The copyright owner has no objection to the facsimile reproduction by anyone of the patent document or the patent disclosure, as it appears in the Patent and Trademark Office patent file or records, but otherwise reserves all copyright rights whatsoever. 37 CFR § 1.71 (d), (e).

### TECHNICAL FIELD

The present invention relates to motor status monitoring and equipment protection applications for industrial automation, heating, ventilation, and air conditioning (HVAC) systems, and other implementations; and, more particularly, to use of current sensors in detecting loss-of-flow conditions.

### BACKGROUND

Often in industrial automation, HVAC, and other applications, current sensing devices can be employed to offer an ability to trigger a set of contacts or to provide an analog or digital output signal and/or control signal based on sensed current. Such devices can be particularly useful in many motor control and/or monitoring applications.

Motors, fans, pumps, and other electromechanical devices typically operate using an electrical power source that has a constant frequency, such as 50 or 60 hertz. In industrial HVAC systems, such as an air conditioning system, as but one example, a motor can be coupled with a belt in order to drive a fan for purposes of circulating air through building ductwork. In order to facilitate remote detection of problems in the operation of the motor, belt, and/or fan (such as a broken belt, etc.), prior systems have employed one or more pressure transducers mounted in the ductwork to sense the air pressure values. If problems occur, such as the motor stopping, the belt breaking, of the fan breaking or jamming, the sensed air pressure in the ductwork typically exhibits a measurable pressure decrease. Pressure transducers sense such a decrease in the air pressure and can trigger an alarm signal. In a similar manner, tachometers can be used to monitor shaft rotations, belt travel distance, etc. for purposes of assessing operating status of motors connected to conveyor systems.

Unfortunately, pressure transducers and tachometers need to be installed using a time-consuming and error-prone process involving manual adjustment to set the desired threshold used to indicate that an alarm condition has been detected. Also, because pressure transducers are susceptible to accumulating dust and dirt, their performance and reliability can diminish over time. They often can require additional labor in the form of maintenance, which adds to their ongoing operating costs. Furthermore, the cost of pressure transducers can be too expensive for many applications and they often require external power for operating, which can limit the applications in which they can be used.

An alternative approach can employ current sensors to sense current levels in the conducting power cable supplying the motor. The sensed current can provide information about the status of equipment, such as motors, belts, fans, etc., connected to the system. If a connected belt breaks, as but one example of a system failure or alarm condition, the sensed current level typically exhibits a substantially significant drop in amperage. A current sensor can detect the current decrease and indicate the alarm condition and/or generate an appropriate output signal and/or control signal.

In one embodiment of a monitoring system employing a current sensor, a current transformer can be installed to sense alternating current within a conducting wire, such as a power cable supplying operating power to a motor. As previously mentioned, other electrical and/or electromechanical devices, such as pumps, fans, conveyors, etc. may also be used, consistent with the principles of the present application, instead of or in addition to a motor device. A typical inductive current transformer can be a wire wrapped toroidal core surrounding the power cable. It can generate an output voltage signal at its terminals in the secondary winding that is proportional to or otherwise indicative of the sensed current in the power cable. On installation, the current sensor is configured or positioned so that the current conductor passes through the transformer core, and the core magnifies the conductor's magnetic field. An AC current source has a potential that is constantly changing between positive and negative values, generally at a set rate, such as 50 or 60 Hz. The expanding and collapsing magnetic field can induce a current in the secondary windings around the core. This secondary current is converted to a voltage and conditioned to provide a desired output signal. The toroidal core can be an iron core or an air core (a non-magnetically permeable material), as but two examples.

A traditional current sensor set-up procedure includes installing the current sensor unit, and starting the motor so that current is running through the current sensor. Then, the operator would have to reach inside the energized electrical panel with a small screwdriver (like a jewelers screwdriver) and adjust a multi-turn potentiometer, such as a “20-turn” or “30-turn” potentiometer (hereinafter “pot”), to name but a few examples. The multi-turn potentiometer is turned multiple times in one direction until over/under LEDs toggle. For any traditional, commercially available current sensor, there is typically a specified (often imprecise, confusing, or complex) procedure for setting the current sensor once it is installed and energized. For example, one such procedure can require using a tiny jeweler's screwdriver to turn a multi-turn potentiometer multiple times it until a light changes illumination state, and then turning the pot back in the other direction a quarter or half turn, etc.

A multi-turn pot is typically referred to as a “20-turn pot,” etc. because it is internally geared for a given number or turns. It can be 4, 10, 20, 25 turns etc, but it is typically multiple turns because the set point for these types of sensors typically exhibit non-linear characteristics (e.g., exponential or logarithmic scaling, etc.). For example, if one were to try to use a 1-turn pot with a 300-degree span of rotation, approximately the first half of the rotational range (e.g., 150 degrees) would approximately represent only a quarter of the scaled range, whereas the regaining three quarters of the scaled range would be crammed around the other 150 degrees of rotation.

This non-linearity results in inconvenient scaling. For example, by way of further illustration, the 8 o'clock position of the pot might be the setting for a 1 Amp trip point. The 12 o'clock position might represent a 3 Amp trip point. However, rotation to the 2 o'clock or 3 o'clock position might represent a 30 Amp trip point, and 50 to 135 Amps might be bunched up near the end of the rotational range. As a result, with a traditional current sensor, it can be next to impossible to dial in a particular desired current on a single turn pot.

As previously mentioned, traditional current sensors are calibrated after starting the motor (and/or other equipment) that is being monitored. Once the current sensor is energized, a jeweler's screwdriver is used to rotate a tiny sensor adjustment screw until the sensor visually indicates that it is at its detection threshold. LED indicators are typically provided to give feedback as to whether the threshold has been set above or below the current being monitored, but there is no way to dial the current sensor directly to a desired current. With prior current sensors, this procedure has been accepted as necessary because the normal run current may not be known by the installer and, even if the run current were known, there is no scaling dial on the adjustment screw to correlate the value of the sensor detection threshold setting to the motor run current. It would also be impractical to have a dial scale on a conventional sensor because the adjustment screw regularly requires multiple turns, due to the non-linear characteristics of the current sensing circuitry.

Unfortunately, in addition to being inconvenient, the traditional methodology for calibrating previous current sensors is also expensive and dangerous. Installers are required to install current sensors in all desired locations, start-up the motor and energize the system, and then return to each install site to calibrate each current sensor. The installer is also placing his or her hand (and a screwdriver) in an energized enclosure, which presents a dangerous situation. Also, existing current sensor embodiments would require someone in the field to conduct a calculation to discount full load amperage by some chosen amount if loss-of-flow detection is desired.

Recently, microprocessor current sensor embodiments have been used for use in proof of flow detection, as an improvement to overcome complexity with the 30-turn pot. However, microprocessors are power-hungry, expensive, and they do not work in all applications (e.g., with Amperage levels less than around 2 A—which does not provide sufficient power for operating the microprocessor). Also, they can often prove to be inflexible regarding adjustments for unusual applications.

### SUMMARY

Embodiments consistent with the present application offer substantial improvements over traditional current sensors and current sensor switches that are commercially available for use in proof of flow applications. In one aspect of the present application, an improved current sensor embodiment can be provided that includes a circuit design and components that exhibit, at least in part, calibration that employs substantially linear scaling. By using linear scaling, a one-turn potentiometer can be employed for convenient calibration prior to installing and/or energizing the current sensor. Embodiments consistent with the present application can also include a calibration scale conveniently provisioned proximate to and/or in cooperation with an adjustment control for the one-turn pot. Providing a calibration scale can enable the installer to calibrate the sensor prior to installation, which eliminates the need to perform calibration inside an energized motor starter or return to the install location for calibration after the system in energized. As an additional advantageous aspect of the present application's subject matter, current sensor embodiments can employ a knob, dial, or other manual control to facilitate the calibration prior to installation, or for subsequent readjustment to accommodate subsequent system configuration changes, as necessary.

To further facilitate installation and/or simplify the calibration procedure for proof of flow applications, embodiments as disclosed herein benefit from improved electronic calibration circuitry and/or circuit design elements that automatically establish a corresponding trip point once a linearly scaled set point manually has been set. The trip point can be established at a set percentage below the set point manually selected by the installer. Such embodiments can use a pre-set percentage that can be, at least in part, substantially representative of an expected current decrease in response to the occurrence of one or more conditions that can result in a loss of flow. Embodiments can also use as a set point a value that is convenient for an installer to determine. One such embodiment can allow an installer to set the current sensor to an easily ascertained value such as the full load amperage (“FLA”), which can be readily determined from a name plate for an applicable motor/device, from system plans, and/or from another convenient source. Based, at least in part, on the FLA setting indicated, such a current sensor embodiment can automatically establish a trip point that is at a predefined percentage less than the installer-indicated FLA such that is can be automatically and appropriately configured and/or set for detecting proof of flow for the provided FLA value.

To provide additional flexibility and/or convenience, current sensor embodiments consistent with the present subject matter can, as one additional and/or alternative aspect, be designed employing a housing that can substantially accommodate the addition and/or removal of components such as control relays from a convenient location and/or configuration, such as the face of the current sensor unit, as but one example.

Embodiments employing individual or combinations of the previously described aspects can offer simplified, compact current sensor devices that can be economical to build, inventory, distribute, and purchase, and can offer proof of flow detection in a variety of potential system configurations, each of which can have potentially different current levels and operating characteristics. Additionally, present embodiments can provide increased safety benefits for the installer, facilitate a simplified calibration procedure, and result in decreased labor costs for installation, replacement, and/or adjustment of units embodying the present subject matter.

Additional aspects and advantages of this invention will be apparent from the following detailed description of preferred embodiments, which proceeds with reference to the accompanying drawings.

### BRIEF DESCRIPTION OF THE DRAWINGS

FIG. 1 illustrates one embodiment of a system configuration consistent with the present subject matter.

FIGS. 2A-2B illustrate alternative embodiments of a current sensor apparatus consistent with the present subject matter.

FIG. 3A depicts a schematic of circuit components representative of traditional current sensors.

FIG. 3B depicts a schematic of circuit components consistent with an embodiment of the present subject matter.

FIGS. 4-10 depict various individual component and partially assembled views of one embodiment of a current sensor design consistent with the present subject matter.

FIGS. 11A-11D illustrate alternative embodiments of scaled current sensor labels consistent with the present subject matter.

### DETAILED DESCRIPTION OF PREFERRED EMBODIMENTS

The following detailed description references apparatuses, systems, and methods embodying one or more principles of the invention consistent with the present application. It should be appreciated that the following embodiments are disclosed for illustrative purposes. The various components, structures, configurations, operating ranges, and/or other aspects of the disclosed embodiments are not meant to indicate limitations on the present invention. Those skilled in the relevant art will appreciate that the disclosed embodiments can be modified with fewer, additional, and/or alternative element without departing from the scope of the present invention.

One embodiment can employ inventive circuitry design and/or components to provide improved current sensor devices that can have substantially simplified calibration procedures for initial installation and/or subsequent adjustment. For example, an embodiment can include a potentiometer (hereinafter “pot”) wired into a circuit so as to be configured for substantially linearly adjustable resistance values over the range of motion of the pot adjustment mechanism. As used herein, the terms “linearized” and/or “linear” are used to indicate a relationship whereby substantially the same amount of resistance adjustment and/or corresponding change in output signal can be achieved for a given number of degrees of rotation of the pot adjustment mechanism. This can help spread the scale of settings out substantially evenly around the adjustment range.

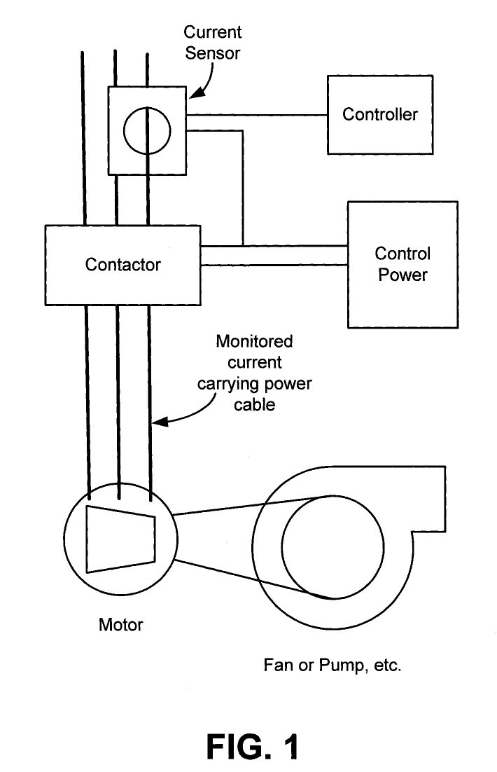

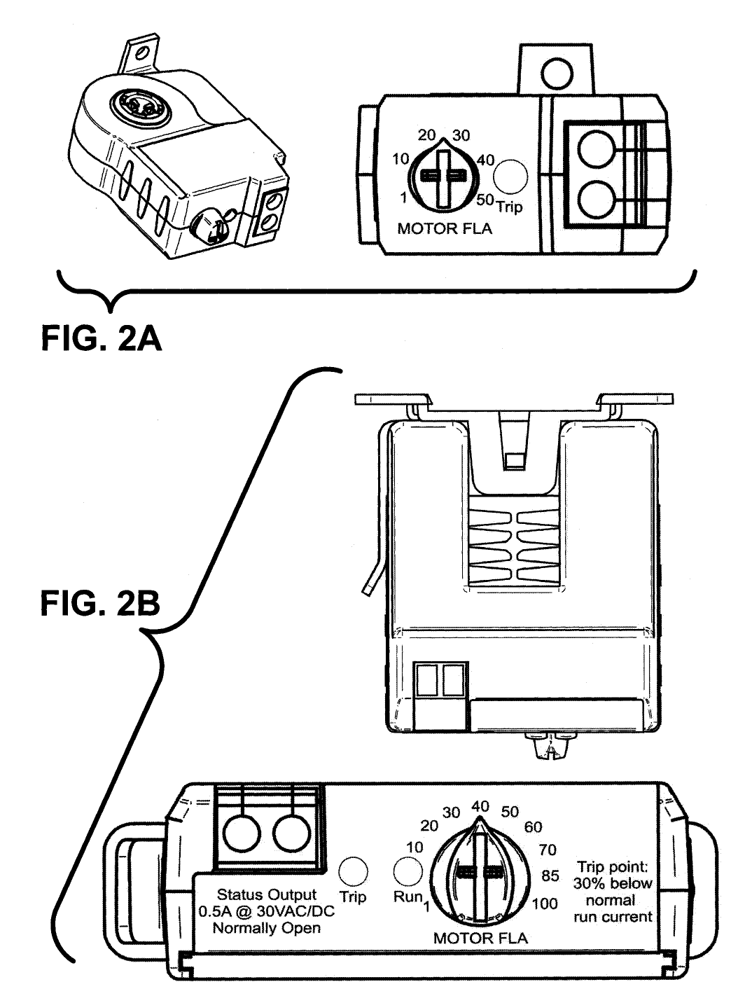

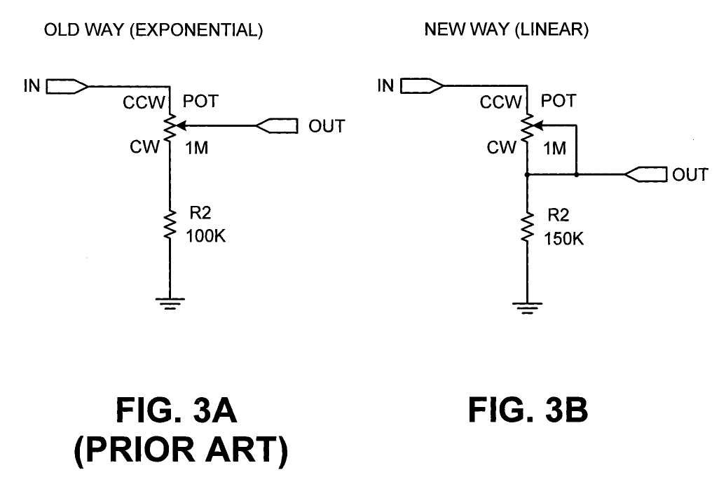

FIG. 1 illustrates a general system configuration and FIGS. 2A and 2B each represent alternative embodiments of current sensor devices consistent with the present subject matter. FIG. 3B depicts a partial current sensor schematic illustrating one embodiment of linear calibration circuitry and/or circuit components employing a novel configuration in the pot wiring, resulting in improvements over the traditional non-linear designs typical of past current sensors (which are represented by the illustrative partial schematic of FIG. 3A).

The way the pot is configured in the circuitry can provide significant benefits by way of the linear relationship, such as by allowing the use of a 1-turn pot. Employing a pot in a circuit exhibiting linear characteristics allows for the use of a 1-turn pot, as opposed to the inconvenient 20- or 30-turn pots typical of prior art applications.

Also, the linear relationship can make the use and provisioning of a scaled range for use in setting the pot. However, it is worth noting that the incremental spacing of the displayed scale may not be exactly linear (e.g., the magnitude of the current values between gradations or settings on the scale may not be exactly equal). This is mostly due to non-linearity in the magnetic characteristics of the circuit and/or second order non-linear effects of non-ideal electronic components. However, present embodiments enjoy scaling that is sufficiently linear to allow for the convenient printing of numbers, visible to an installer, on a scale substantially in a circle around, or otherwise conveniently proximate to, an adjustment control of the pot (assuming the pot is rotationally adjusted—although other pot embodiments, such as a slider pot could also be used and appropriately include scaled values in a straight line configuration corresponding to the range of pot movement).

An embodiment can employ novel design aspects that can, at least in part, offer a substantially improved and simplified experience for installers, mechanics, etc. One such embodiment can provide a pre-assembled, integrated, coupled, and/or otherwise conveniently provisioned manual control for setting or adjusting the pot. As one illustrative type of control, one adjustment control can be embodied as a knob configured, at least in part, to be gripped and turned by hand (so that an installer, etc. does not have to use a screwdriver for setting/adjusting the pot). Other manual controls, such as dials, etc. can also be used. One or more embodiments offering a control, such as a knob, in combination with a scale can make it conveniently possible for an installer to set the current sensor to a selected current value before it is installed in and/or energized within an electrical enclosure.

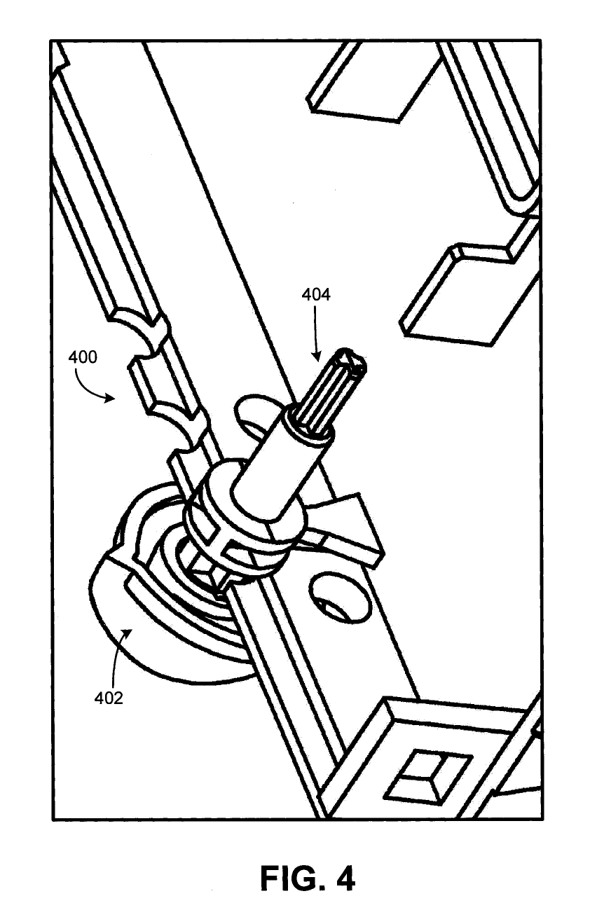

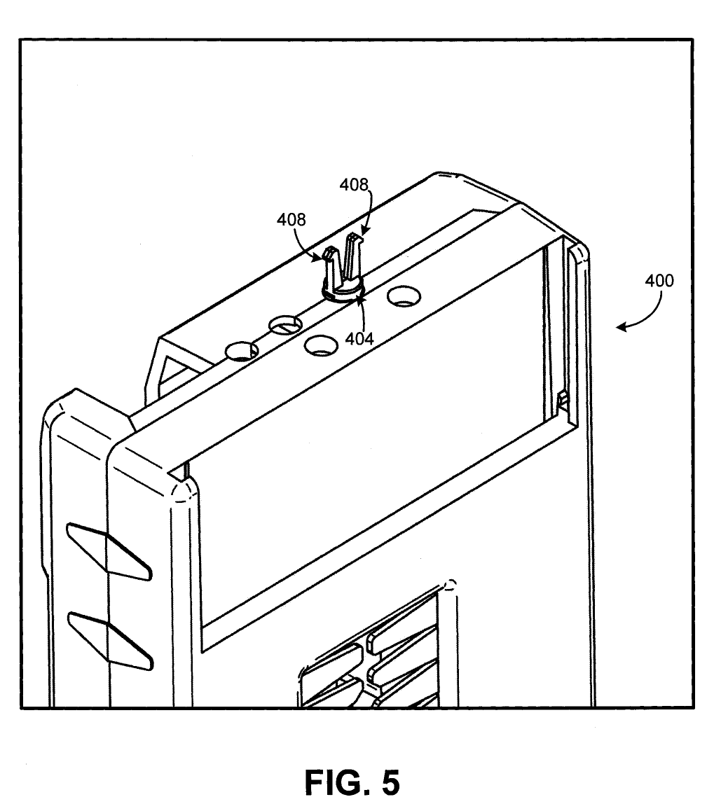

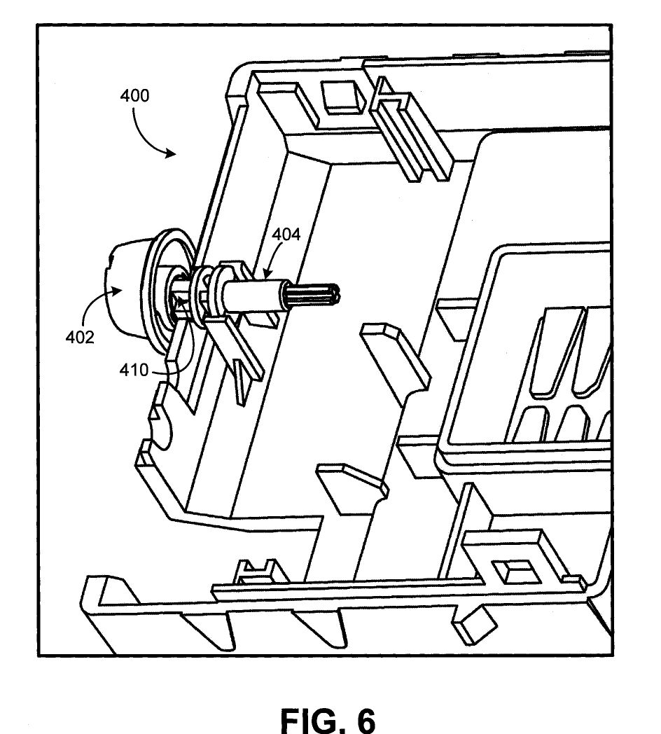

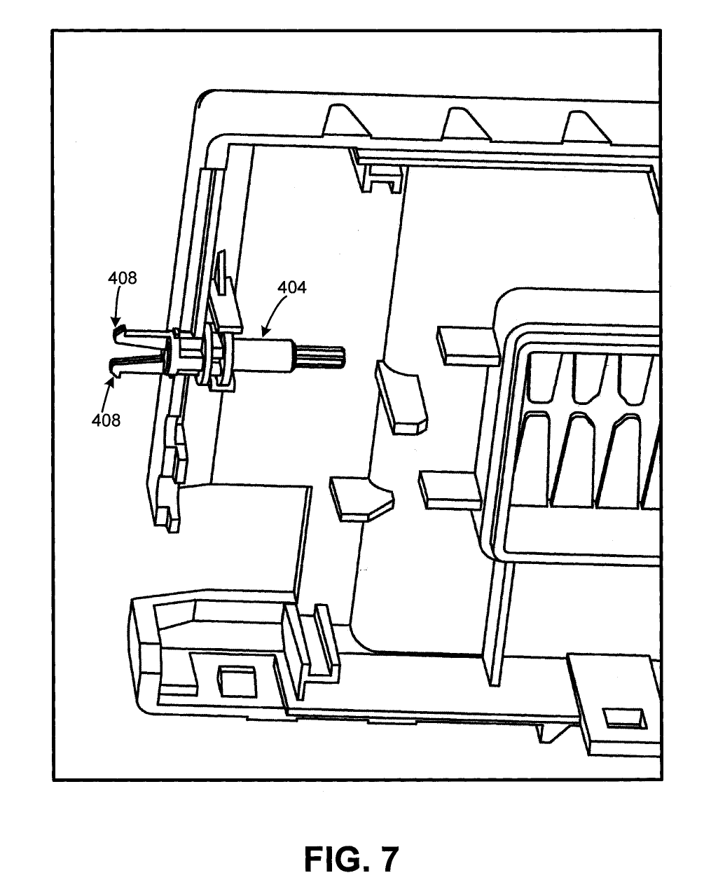

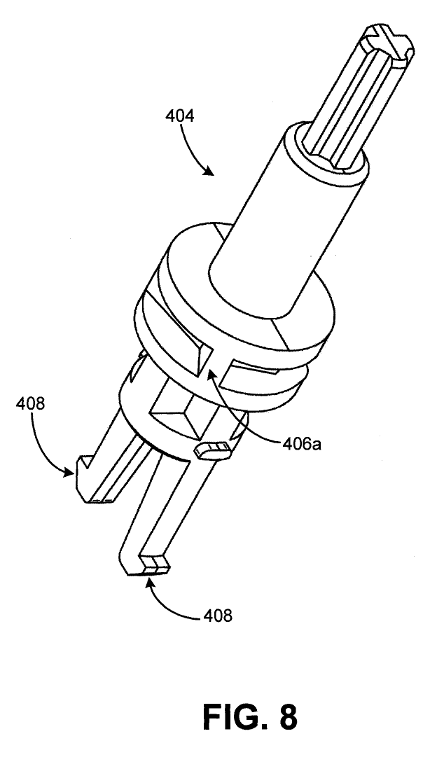

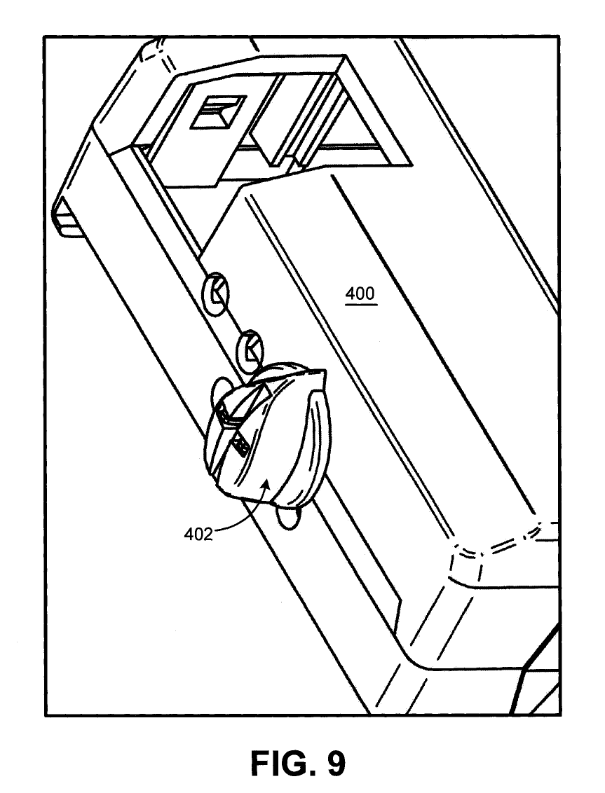

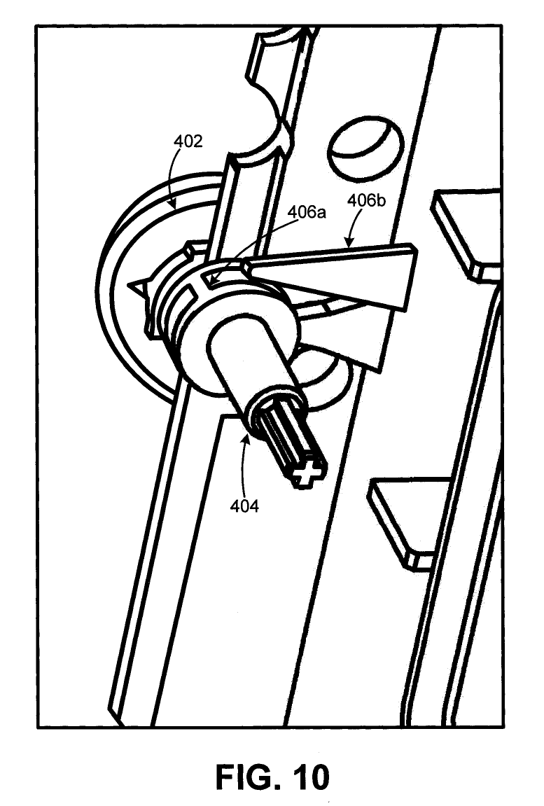

FIGS. 4-10 illustrate various exploded and detailed views of one embodiment of a current design consistent with the present application. Such embodiment is, however, depicted only for illustrative purposes and to facilitate discussion. The present subject matter is not meant to be limited by or to the particular embodiment illustrated.

As illustrated in FIGS. 4-10, embodiments consistent with the present subject matter can include a current sensor 400 employing an adjustment control comprising a two-part assembly of a knob 402 and shaft 404. It can also include a mechanical stop 406a and 406b to protect the potentiometer and shaft components. A mechanical stop can be provided on shaft 404 and/or knob 402 to help prevent the pot from being over-tightened, which can lead to potential breaking of the component on the circuit board or breaking the pot shaft. An embodiment can also include a friction mechanism (not shown) to prevent the pot from turning by itself due to vibration, gravity, accidental/inadvertent contact, or other causes. Detail in the tooling can additionally and/or alternatively provide friction forces to help hold the knob in place. Also, an embodiment can be constructed comprising an internal collar 408 on shaft 404 to engage a lip or flange 410 on the underside of knob 402 in order to help prevent unwanted and/or unintentional removal of knob 402.

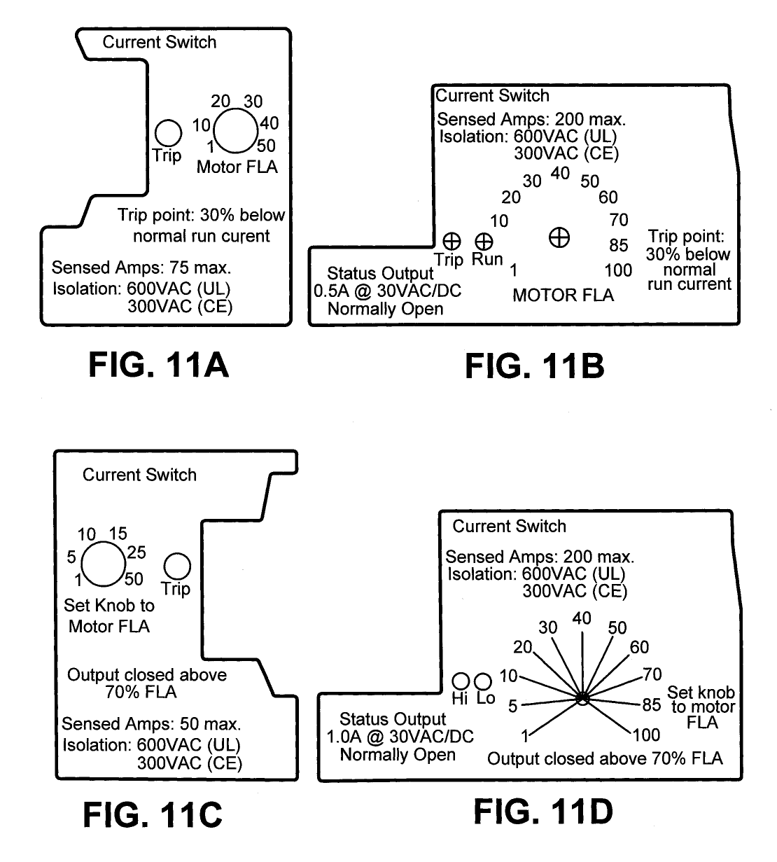

In one embodiment, the knob and the shaft can comprise a two-piece design that can accommodate a label being applied to the product with the knob subsequently being snapped over the top of the label. A label, such as those embodiments depicted in FIGS. 11A-11D, can include depictions of the numbers and/or other indicia of the scaled range of the pot. Employing this component construction can help a manufacturer avoid having to use a cutout on the label that is big enough to accommodate a pre-assembled or integrated knob. When a scale is provided on such a label, having a relatively reduced-size cutout allows the scaled values to be located closer to the adjustment control, which subsequently can improve accuracy and ease of reading when adjusting the pot. Additional and/or alternative information can also be provided on the label (user installation instructions, configuration information, intended operation characteristics, etc).

Embodiments having a knob or other manual adjustment control can offer distinct advantages for installers, mechanics, and other users. For example, an embodiment providing a knob and scale can make it convenient for a user to set the current sensor before it is installed or electromagnetically coupled with a hot current conductor. This enables the installer to calibrate the sensor before running the motor, which presents a significant safety benefit. An installer can install the current sensor in the intended electrical box/panel and the current sensor can be already scaled for the intended application. The installer can install it without having to put his or her hands in an enclosure when the enclosure is energized.

In addition to safety benefits, such embodiments can offer increased convenience, reduced cost of installation, and other advantages, while employing a design that is more economical to manufacture than a traditional design, and can be significantly cheaper and/or more useful in broader range of applications than current sensor designs employing expensive microprocessors. Many microprocessors typically cannot be used in applications that do not have over 2 amps. Unfortunately, an overwhelming majority of motors relevant to the present application are 10 amps or less, and a substantial percentage of those are below 2 amps in size. Embodiments as disclosed herein, however, can function at much lower current levels, such as levels below 2 amps, or even 0.1 amp or below. Of course, these values are provided for illustration and to facilitate discussion; they are not intended to limit the claimed subject matter.

Present embodiments can offer a substantially improved design and/or user/installer experience. Such embodiments can allow a user to use a conveniently ascertainable value as the set point for configuring the current sensor. The current sensor can then automatically employ an appropriate trip point consistent with the intended application or desired functionality. As but one example, a current sensor can be provided employing a simplified construction, design, and/or electronic characteristics that make it pre-configured and/or pre-designed for a specific intended use, such as proof-of-flow monitoring for a motor and/or other device.

As one example, described for illustrative purposes, and not by way of limitation, one embodiment of an apparatus in a proof-of-flow application can comprise a current sensor with a substantially linearly scaled pot that allows a user/installer to provide a conveniently ascertainable value, such as full load amperage (“FLA”) of the motor or other monitored device, as a set point value. The resulting output can be an alarm, and/or an analog or digital signal and/or other output appropriate for a proof-of-flow application. FLA can be taken off a motor name plate, off the building and/or system schematics or plans, and/or determined from other convenient sources, such as from an overload protection device that may be installed on the system, or from design specifications. FLA can be used, at least in part, because it can be easily known or ascertained by someone on site. Using the knob, and with reference to a indicated scale (printed on attached labeling, molded directly into a housing, and/or otherwise provisioned for reading), the installer can conveniently and accurately manually set the amperage for the current sensor to the appropriate FLA value and then install the current sensor in its intended location. The current sensor can be preconfigured so that, given that the selected value is a FLA set point, the current sensor can trip and/or alarm/signal if there is an appropriate amount of current loss (e.g., a trip point value below the FLA set point amperage is used, for a proof of flow application).

For a proof-of-flow application, a current sensor embodiment can be pre-configured to employ a trip point that is substantially below the amperage represented by the knob setting (e.g., FLA). Applicants have determined that in proof of flow monitoring, a sensed current loss of between 20-35% is commonly experienced in response to a loss of load (e.g. belt break/loss or other mechanical failure). In certain applications, a loss of up to 40% or more can be experienced (e.g., if you have a belt brake on a fan, as but one example). Of course, those skilled in the art will appreciate that alternative applications can potentially result in other expected loss levels. A present current sensor embodiment can be scaled so that for a given set point, it will employ a corresponding trip point that is proportionally less than the set point. The quantity of offset can be preconfigured at a given value, such as 30%, as but one example, below the FLA set point. Such an embedment can offer a simple, convenient, and easy to use current sensor apparatus that can be pre-scaled application specific for proof of flow. Generally speaking, for any given install environment, it is desirable to employ a trip point that is set far enough below FLA to avoid experiencing undue quantities of false trips, but close enough to FLA to rapidly and accurately detect loss of flow occurrences. It should be appreciated, however, that additional and/or alternative embodiments could employ different scaling methodologies, pre-set and/or field-configurable, for other applications, other types of monitoring, or other desired functionality.

To use a traditional adjustable current sensor for proof of flow applications, someone in the field would be required to conduct a calculation or other adjustment to discount FLA or running current by an appropriate amount to conduct proof of loss determinations. For example, a traditional current sensor set at 10 amps would be expected to trip (or signal/alarm) substantially at the set point of 10 amps. To trip at a lower set point, an installer would have to turn a multi-turn pot back a increased amount during calibration. However, such a procedure provides uncertain and imprecise results. With present embodiments, a setting of 10 amps would result in a trip point at 7 amps, if a 30% offset is used. An alternative embodiment could be configured to trip at 6 amps, or some other trip point value offset from the set point by a quantity specifically selected for the specific proof of flow application.

Consistent with the present subject matter, a current sensor can be installed with a convenient, intuitive procedure. For example, one current sensor embodiment can be made commercially available for a range of appropriate current levels, such as 0-50 amps, in one example. The installer can simply look at the name plate on the actual motor being monitored and determine what the FLA is for that motor. The installer can then turn the dial on the pot (preferably by hand using an integrated knob) to the FLA value and install the device. As previously discussed, having a substantially linear calibration circuit adjustment can allow embodiments to employ a convenient single-turn pot. And, with a single turn pot, it is also convenient and practical to print a dial scale on the label that corresponds and functions in cooperation with the dial/knob. The internal trip point threshold setting of the sensor can be set to 60%, or another chosen percentage, of the FLA value printed on the label and selected using the knob dial.

For increased accuracy/reliability, improved performance, and/or other advantageous reasons, additional and/or alternative embodiments consistent with the present subject matter can accommodate one or more applicable operating assumptions. For example, Applicants have determined that, in typical applications, a properly loaded motor will run at approximately 80-90% of its nameplate FLA. This expected decreased current level substantially represents the normal operating current for the motor/system. In other words, the FLA value can be 10% or more overstated from the level of current a properly loaded motor would be expected to actually draw while running normally for the applicable installation. When a belt breaks, or other load loss is experienced, the current load is expected to further decrease, in some applications up to 40% or more from FLA. For example, a motor with a FLA nameplate value of 100 amps can be assumed to run at 80-90 amps when it is properly loaded. When the belt breaks, the current can be expected to drop again, possibly to 60 amps, in the present example. The internal settings of present embodiments can be designed to accommodate both types and/or instances of expected current drop substantially without requiring actual measuring of running current. Such embodiments can offer improved accuracy and reliability while maintaining the advantage of allowing an installer to calibrate a current sensor embodiment before it is installed in an energized enclosure.

As a further example, if a motor has an FLA of 10 amps, the current sensor can assume the running current is actually 9 amps. The current sensor can then use an offset of pre-determined quantity (such as a percentage between 20 and 35%, as one example) from the 9 amp value to establish a trip point for the sensed current. Of course, additional and/or alternative embodiments could be provided that establish a trip point only with reference to the provided FLA set point, and without discounting the provided FLA value to represent expected normal running current.

Of course, those skilled in the relevant art will appreciate that the above ranges are presented for illustrative purposes and to facilitate discussion. Expanded, reduced, and/or alternate ranges could also be applicable for a given specific application. The values used by current sensor embodiments should, however, be selected so as to provide set and/or trip points appropriate for the expected parameters/characteristics of the application within which the current sensor embodiment is intended to operate. Giving weight to application-specific performance or requirements can make it possible to offer multiple versions of a current sensor device, each one of which can be preconfigured to correspond to specific implementations, levels of fault tolerance, performance levels, or other desired considerations. As but one example, current sensor embodiments can be offered in high-sensitivity and low-sensitivity versions (e.g., a high-sensitivity sensor might be configured to trip at 20% below FLA, while a low-sensitivity version can be configured to trip at 30% below the a 10% discounted FLA). These alternative embodiments can be offered as separate and discrete devices, or a single device can be constructed with a switch or other control that can allow a user to select the desired sensitivity level configuration. Of course, other variations can also be provided for employing additional and/or alternative embodiments equally consistent with the claimed subject matter.

As one example of a variation that can be provided as one aspect of an additional and/or alternative embodiment, LEDs and/or other visual indicators can be provided with current sensor embodiments to allow an installer to perform a calibration substantially consistent with the methodology used with traditional current sensors, either for providing the installer with the option to use a more familiar procedure, or for applications that substantially do not conform to the assumptions or pre-set loss of flow settings employed by a given current sensor embodiment.

Additional and/or alternative embodiments can also encompass current sensor devices comprising a housing that can substantially accommodate the addition and/or removal of components such as control relays from a convenient location and/or configuration, such as the face of the current sensor unit, as but one example. Such embodiments can offer one or more of the advantages described above in an additionally convenient an all-in-one package that can provide switching for device protection, automation control, and/or other purposes.

It will be obvious to those having skill in the art that many changes may be made to the details of the above-described embodiments without departing from the underlying principles of the invention. The scope of the present invention should, therefore, be determined only by the accompanying claims.

1. A system for detecting loss of flow or other load loss, comprising:
a current sensing circuit including:
a current transformer for measuring current to a load;
calibration circuitry configured to employ a current value selected from among a range of current values; and
an adjustable potentiometer for adjusting the calibration circuitry to employ the selected current value; and
a calibration scale indicating the range of current values and provisioned proximate to the adjustable potentiometer so as to facilitate adjustment of the calibration circuitry consistent with the selected current value.

2. The system of claim 1, wherein the selected current value is selected based at least in part on a characteristic of the load.

3. The system of claim 1, further comprising a manual adjustment control coupled to the potentiometer.

4. The system of claim 3, wherein the manual adjustment control is constructed to facilitate adjustment by hand.

5. The system of claim 1, wherein the range or current values are approximately evenly distributed along the calibration scale.

6. The system of claim 1, wherein the calibration circuitry exhibits a substantially linear relationship between a position of the adjustable potentiometer and corresponding current value from within the range of current values.

7. The system of claim 1, wherein the adjustable potentiometer is a one-turn potentiometer.

8. The system of claim 1, wherein:
the current sensing circuit is disposed within a housing; and
the housing is configured to cooperatively accommodate an command relay.

9. A current sensor apparatus, comprising:
a current sensing circuit having calibration circuitry substantially linearly scaling a range of current values for selection by a user;
a manual adjustment control configured for selecting a current value from among the linearly scaled range of current values;
a calibration scale provisioned proximate to the manual adjustment control for facilitating a selection of the current value.

10. The apparatus of claim 9, wherein the current sensing circuit includes a one-turn potentiometer.

11. The apparatus of claim 10, wherein the one-turn potentiometer is coupled to the manual adjustment control, whereby positioning the manual adjustment control correspondingly positions the one-turn potentiometer.

12. The apparatus of claim 9, wherein the manual adjustment control is a knob configured for adjustment by hand.

13. A method comprising:
identifying a current value for use in monitoring proof of flow for a load;
manually setting a current sensor to the current value;
employing the current sensor with the manually set current value to sense current to the load.

14. The method of claim 13, wherein manually setting the current sensor to the desired current value occurs before the current sensor is energized.

15. The method of claim 13, wherein the current value is the full load amperage for the load.

16. The method of claim 15, further comprising determining the full load amperage from one of a motor name plate or a system plan.

17. A method comprising:
configuring a current sensing circuit of a current sensor to accommodate substantially linear calibration of the current sensor to a selected current value using a potentiometer;
coupling a manual adjustment control to the potentiometer to facilitate an installer in setting the selected current value;
provisioning a calibration scale proximate to the manual adjustment control to facilitate calibration of the current sensor to the selected current value consistent with the calibration scale.

18. The method of claim 17, further comprising provisioning the calibration scale with current values displayed in approximately evenly spaced increments.

19. The method of claim 17, further comprising configuring the current sensing circuit to monitor for measured current values that are more than a specified amount below the selected current value.

20. The method of claim 19, where the specified amount is an empirically determined percentage of the selected current value.
